(19) United States
(12) Patent Application Publication
(10) Pub. No.: US 2008/0236496 A1
(43) Pub. Date: Oct. 2, 2008

(54) VACUUM EVAPORATION APPARATUS

(75) Inventors: Yukihisa NOGUCHI, Odawara-shi (JP); Hiroshi SOHDA, Odawara-shi (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM CORPORATION, Tokyo (JP)

(21) Appl. No.: 12/059,616

(22) Filed: Mar. 31, 2008

(30) Foreign Application Priority Data
Mar. 30, 2007 (JP) 2007-090566

(51) Int. Cl. C23C 14/24

(52) U.S. Cl. 118/726

(57) ABSTRACT

The vacuum evaporation apparatus includes a vacuum chamber, a substrate holder which is disposed in the vacuum chamber and holds a substrate, and an evaporation source which is disposed in the vacuum chamber and evaporates a film-forming material. The substrate holder has a substrate holding portion which is made of a first material having a heat conductivity of at least 100 W/m·K and a specific gravity of up to 4.0×10³ kg/m³ and a vapor deposition area-regulating member which is made of a second material that is different from the first material and has a melting point of at least 1300° C. This apparatus is capable of preventing a film-forming material from being deposited on the substrate holder surface while keeping the temperature within the substrate holder uniform.

The entire contents of a document cited in this specification are incorporated herein by reference.

### BACKGROUND OF THE INVENTION

The present invention relates to a vacuum evaporation apparatus that may be advantageously used to manufacture radiation detectors used in medical diagnostic devices and nondestructive testers.

A radiation image detector which records a radiation image by first allowing a radiation (e.g. X-rays, α-rays, β-rays, γ-rays, electron beams or uv rays) to pass through an object, then picking up the radiation as an electric signal has conventionally been used in such applications as medical diagnostic imaging and industrial nondestructive testing.

Examples of this radiation image detector include a solid-state radiation detector (so-called “flat panel detector” which is also hereinafter abbreviated as “FPD”) that picks up the radiation as an electrical image signal, and an X-ray image intensifier that picks up the radiation image as a visible image.

FPDs are operated by one of two methods, direct and indirect; in the direct method, electron-hole pairs (e-h pairs) emitted from a film of photoconductive material such as amorphous selenium upon incidence of a radiation are collected and read as an electric signal, whereby the radiation is “directly” converted to the electric signal; in the indirect method, a phosphor layer (scintillator layer) which is formed of a phosphor that emits light (fluoresces) upon incidence of a radiation is provided such that it converts the radiation to visible light, which is read with a photoelectric transducer, whereby the radiation “as visible light” is converted to an electric signal.

In manufacturing the aforementioned radiation detector, vapor deposition (vacuum evaporation) is commonly used to deposit a phosphor to a predetermined thickness on an optical detector. Compared with a phosphor layer produced by an application method which involves preparing a coating solution by dispersing powder of a phosphor in a solvent containing a binder and other necessary ingredients, applying the coating solution to a support sheet made of glass or a resin, and drying the applied coating, a phosphor layer formed by vapor deposition has superior characteristics in that it is formed in vacuo and hence has low impurity levels and that being substantially free of any ingredients other than the phosphor as exemplified by a binder, the phosphor layer has not only small scatter in performance but also features very highly efficient luminescence.

In the aforementioned film deposition apparatuses of a vacuum evaporation system (hereinafter referred to as the “vacuum evaporation apparatuses”), a substance for vapor deposition (a phosphor) is deposited not only on the support (substrate) sheet made of glass or resin but also on the inner wall surface of the vacuum chamber where vapor deposition is performed, so that a detachable protection tool called “deposition preventing plate” is usually attached to the inner wall surface of the vacuum chamber in order to facilitate the maintenance work performed as a post-process, including removal of the phosphor deposited at undesired portions. The substance for vapor deposition (phosphor) is thus prevented from being deposited on the inner wall surface of the vacuum chamber during the vapor deposition step, which enables the maintenance work of the vacuum evaporation apparatus to be minimized to replacement of the aforementioned deposition preventing plate, thus considerably reducing the cost and time for cleaning the inner wall surface of the vacuum chamber.

The “film deposition apparatus” described in JP 2001-316797 A is an example of the film deposition apparatus equipped with this type of deposition preventing plate. This film deposition apparatus is the one which includes a substrate carrier for holding and transporting a substrate and forms a film by depositing particles of a vapor deposition material on the substrate set on the substrate carrier, and is characterized in that a detachable deposition preventing member which prevents particles of a film-forming material from being deposited in the area other than the substrate (e.g., on the frame of the substrate carrier) is mounted on the surface of the substrate carrier. This apparatus prevents deposition of a film on the substrate carrier owing to the deposition preventing plate, and need only detach the deposition preventing plate having a film deposited thereon from the substrate carrier and replace it with a new one, thus enabling considerable reduction of the cost and time required for the maintenance of the film deposition apparatus.

### SUMMARY OF THE INVENTION

Apart from this, blasting and more specifically sand blasting and glass bead blasting are commonly known methods for peeling off a film-forming material deposited onto a substrate holder or other components in a vacuum evaporation apparatus, but a vacuum heating system has recently been proposed as a system that does not cause breakage (deformation) of the substrate holder along with increased demands for the film deposition position. As used herein, the “vacuum heating system” involves heating the substrate holder in vacuo to evaporate and remove a film-forming material having been deposited on the substrate holder to clean the substrate holder.

The problem raised here is a limited range of temperature used in the aforementioned vacuum heating system in the case of using an aluminum alloy-based material with a low heat resistance, because the substrate holder to be cleaned is generally made of an aluminum alloy-based material as part of weight reduction for improving the operability.

An option to solve this problem is to change the material of the substrate holder to a highly heat-resistant material such as stainless steel (so-called SUS).

On the other hand, the vacuum evaporation apparatus requires uniform control of the temperature in each portion of the substrate (vapor deposits) to ensure the quality of the vapor-deposited film. However, the aforementioned highly heat-resistant material such as the stainless steel (SUS) is generally low in heat conductivity and raises another problem that excellent performance cannot be achieved in terms of transmitting heat from the temperature adjusting plate to the substrate.

In other words, in the case of using an aluminum alloy-based material in the substrate holder, insufficient heat resistance causes the range of temperature used in the vacuum heating system to be limited. If stainless steel (SUS) as a highly heat-resistant material is used for the substrate holder in order to avoid such a problem, there will arise a problem that the temperature uniformity cannot be achieved within the substrate holder.

In addition, the substrate holder that supports the whole of the substrate is usually large in size and is considerably deflected by its own weight. Deflection due to its own weight, when proceeding during vapor deposition, may adversely affect the film quality.

The present invention has been made to solve the aforementioned conventional problems and it is an object of the present invention to provide a vacuum evaporation apparatus capable of readily removing the film-forming material deposited (vapor-deposited) on the substrate holder surface while keeping the temperature within the substrate holder uniform such that the substrate holder that can be used has substantially free from or very little deposition (vapor deposition) of the film-forming material on its surface.

More specifically, the present invention is aimed at providing a vacuum evaporation apparatus that can be repeatedly used with ease by applying to the portion on the substrate holder surface where a film-forming material is readily deposited, a structure capable of removing the deposited film-forming material by the vacuum heating system.

In order to achieve the above objects, the present invention provides a vacuum evaporation apparatus which evaporates a film-forming material within an evaporation source to deposit by vacuum evaporation on a substrate held by a substrate holder to form a vapor-deposited film on the substrate, comprising:

a vacuum chamber;

the substrate holder which is disposed in the vacuum chamber and holds the substrate; and

the evaporation source which is disposed in the vacuum chamber and evaporates the film-forming material,

wherein the substrate holder comprises a substrate holding portion and a vapor deposition area-regulating member, the substrate holding portion being made of a first material having a heat conductivity of at least 100 W/m·K and a specific gravity of up to 4.0×10³ kg/m³ and the vapor deposition area-regulating member being made of a second material which is different from the first material and has a melting point of at least 1300° C.

Preferably, the vapor deposition area-regulating member is detachably mounted on the substrate holding portion.

It is preferable for the first material to be a member selected from the group consisting of aluminum and aluminum alloys, and for the second material to be a member selected from the group consisting of stainless steels, iron, titanium, platinum, chromium, molybdenum, tantalum, and tungsten.

The substrate holding portion preferably comprises a base disposed on a back side of the substrate, and a frame used to hold the substrate between the base and the frame, the frame comprising a first step portion which is formed inside the frame to hold the substrate, a second step portion which is formed further outside than the first step portion on the back side of the substrate held in the first step portion and is used to fit the base in the frame, and an opening which is formed on a side of a front surface of the substrate and through which the front surface of the substrate is open.

The present invention has a marked effect in realizing the vacuum evaporation apparatus capable of preventing a film-forming material from being deposited on the substrate holder surface while keeping the temperature within the substrate holder uniform.

More specifically, the present invention has a remarkable effect in providing the vacuum evaporation apparatus that can be repeatedly used with ease by applying to the portion on the substrate holder surface where a film-forming material is readily deposited, a structure capable of removing the deposited film-forming material by the vacuum heating system.

### BRIEF DESCRIPTION OF THE DRAWINGS

FIGS. 1A and 1B are sectional views schematically showing the structure of a solid-state radiation detector (FPD) of a thin film transistor (TFT) type that may be manufactured using a vacuum evaporation apparatus according to an embodiment of the present invention;

FIG. 1C is a plan view of the FPD shown in FIG. 1A;

FIG. 2 is a sectional view showing the detailed structure of an exemplary holder that may be used in an embodiment of the vacuum evaporation apparatus of the present invention;

FIG. 3 is a sectional view schematically showing the structure of an embodiment of the vacuum evaporation apparatus of the present invention where the holder shown in FIG. 2 is used; and

FIG. 4 is a flowchart illustrating how to clean a holder that may be used in an embodiment of the vacuum evaporation apparatus of the present invention (remove the deposited film-forming material) by a vacuum heating system.

### DETAILED DESCRIPTION OF THE PREFERRED EMBODIMENTS

On the pages that follow, the vacuum evaporation apparatus of the present invention is described in detail with reference to the preferred embodiments depicted in the accompanying drawings. The following description refers to the case of manufacturing a solid-state radiation detector of the type in which charges generated by irradiation with a radiation are stored and the stored charges are read with a thin film transistor (abbreviated as “TFT”). However, the present invention is not limited to this but may be advantageously applied to the case of manufacturing, for example, a solid-state radiation detector of a so-called optical reading type in which reading is made by making use of a semiconductor material that generates charges upon irradiation with light.

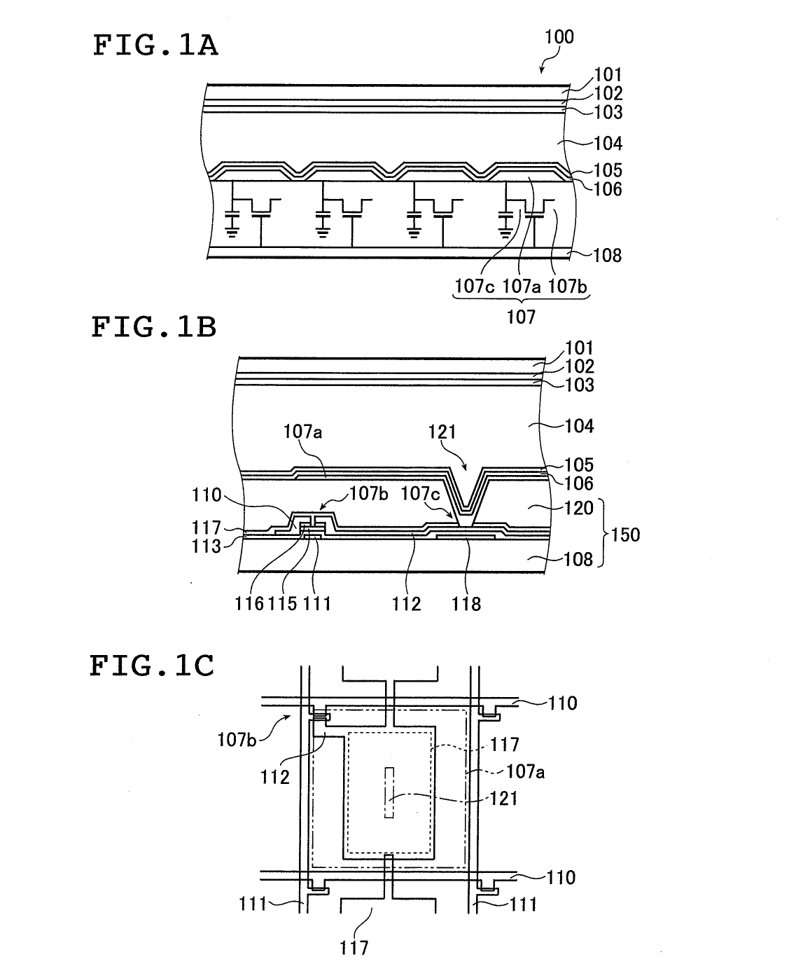

FIG. 1A schematically shows the structure of a TFT type, solid-state radiation detector (FPD) 100 which is manufactured by a vacuum evaporation apparatus of an embodiment to be described later; FIG. 1B is a sectional view of the solid-state radiation detector 100 shown in FIG. 1A which shows the structure on a pixel unit basis; and FIG. 1C is a plan view of the solid-state radiation detector 100 shown in FIG. 1A.

The solid-state radiation detector (FPD) 100 shown in FIG. 1A includes a photoconductive layer 104 which comprises selenium and exhibits electromagnetic conductivity, and a single bias electrode 101 and charge collecting electrodes 107a formed on the upper side and the lower side thereof, respectively. Each of the charge collecting electrodes 107a is connected to a charge storage capacitor 107c and a switching element 107b. A hole injection blocking layer 102 is formed between the photoconductive layer 104 and the bias electrode 101.

An electron injection blocking layer 106 is provided between the photoconductive layer 104 and the charge collecting electrodes 107a, whereas crystallization inhibiting layers 103 and 105 are provided between the hole injection blocking layer 102 and the photoconductive layer 104, and the electron injection blocking layer 106 and the photoconductive layer 104, respectively.

The charge collecting electrodes 107a, the switching elements 107b and the charge storage capacitors 107c constitute a charge detection layer 107, and a glass substrate 108 and the charge detection layer 107 basically constitute an active matrix substrate 150 to be described later.

FIG. 1B is a sectional view showing the structure on a pixel unit basis of the solid-state radiation detector 100 for detecting a radiation image, and FIG. 1C is a plan view of the solid-state radiation detector 100. The solid-state radiation detector shown in FIGS. 1B and 1C has a pixel size of about 0.1 mm×0.1 mm to about 0.3 mm×0.3 mm, and as a whole has a matrix array of about 500×500 to 3000×3000 pixels.

As shown in FIG. 1B, The active matrix substrate 150 has the glass substrate 108, gate electrodes 111, charge storage capacitor electrodes (hereinafter referred to simply as “Cs electrodes”), a gate insulating film 113, drain electrodes 112, a channel layer 115, contact electrodes 116, source electrodes 110, an insulating protective film 117, an interlayer insulating film 120 and the charge collection electrodes 107a. The gate electrode 111, gate insulating film 113, source electrode 110, drain electrode 112, channel layer 115, and contact electrode 116 constitute the switching element 107b which comprises a thin film transistor (TFT). The Cs electrode 118, gate insulating film 113, and drain electrode 112 constitute the charge storage capacitor 107c.

The glass substrate 108 is a support substrate. Use may be made of a substrate of alkali-free glass such as Corning 1737 available from Corning Incorporated for the glass substrate 108. As shown in FIG. 1C, the gate electrodes 111 and the source electrodes 110 form an electrode wiring arranged in a lattice pattern and the switching element 107b composed of a thin film transistor (TFT) is formed at each point of intersection of the two electrodes.

The source and drain of the switching element 107b are connected to the source electrode 110 and the drain electrode 112, respectively. The source electrode 110 has a linear portion for the signal line and an extension for forming the switching element 107b. The drain electrode 112 is provided to connect the switching element 107b with the charge storage capacitor 107c.

The gate insulating film 113 is made of SiNₓor SiOₓ. The gate insulating film 113 is provided so as to cover the gate electrodes 111 and the Cs electrodes 118. The area of the gate insulating film 113 located on each gate electrode 111 acts as the gate insulating film in the corresponding switching element 107b, and its area on each Cs electrode 118 acts as the dielectric layer in the corresponding charge storage capacitor 107c. In other words, the region where the drain electrode 112 is superimposed on the Cs electrode 118 formed at the same level as the gate electrodes 111 constitutes the charge storage capacitors 107c. Not only a simple use of SiNₓ or SiOₓ but also a use of an anodized film obtained by anodizing the gate electrodes 111 and the Cs electrodes 118 is possible for the gate insulating film 113.

The channel layer (i-layer) 115 has channel portions of the switching elements 107b, each of which is a current passage connecting the source electrode 110 with the drain electrode 112. The contact electrode (n⁺ layer) 116 brings the source electrode 110 and the drain electrode 112 into contact with each other.

The insulating protective layer 117 is formed on the source electrodes 110 and the drain electrodes 112, in other words, over the whole surface (substantially the whole surface) of the glass substrate 108 in order to protect the drain electrodes 112 and the source electrodes 110 while providing electric insulation. The insulating protective film 117 has contact holes 121 formed at its predetermined positions, that is, at the positions where the underlying drain electrodes 112 face the Cs electrodes 118.

The charge collecting electrodes 107a are made of an electroconductive, transparent amorphous oxide film. The charge collecting electrodes 107a are formed over the source electrodes 110 and the drain electrodes 112 so as to plug up the contact holes 121. There is electric continuity between the charge collecting electrodes 107a and the photoconductive layer 104 so that charges generated in the photoconductive layer 104 can be collected in the charge collecting electrodes 107a.

The interlayer insulating film 120 is made of a photosensitive acrylic resin and provides electric insulation of the switching elements 107b. The contact holes 121 extend through the interlayer insulating film 120 and the charge collecting electrodes 107a are connected to the drain electrodes 112, respectively. As shown in FIG. 1B, the contact hole 121 formed has a downwardly tapered shape.

A high-voltage power supply (not shown) is connected between the bias electrode 101 and the Cs electrode 118 and applies a voltage between the bias electrode 101 and the Cs electrode 118, thus enabling an electric field to be formed via the charge storage capacitor 107c between the bias electrode 101 and the charge collecting electrode 107a. Since the photoconductive layer 104 is electrically connected in series with the charge storage capacitor 107c, if a bias voltage is applied to the bias electrode 101 in the above process, charges (electron-hole pairs) are generated within the photoconductive layer 104. An electron generated in the photoconductive layer 104 transfers to the positive electrode side, whereas a hole transfers to the negative electrode side, as a result of which charges are stored in the charge storage capacitor 107c.

As a whole, the solid-state radiation detector includes the charge collecting electrodes 107a arranged in a one-dimensional or two-dimensional manner, the charge storage capacitors 107c individually connected to the charge collecting electrodes 107a, and the switch elements 107b individually connected to the charge storage capacitors 107c, such that one-dimensional or two-dimensional charge information can be simply read by once storing one-dimensional or two-dimensional electromagnetic information in the charge storage capacitors 107c and sequentially scanning the switching elements 107b.

An exemplary step of manufacturing the solid-state radiation detector 100 is described below. A film of a metal such as tantalum or aluminum is first vapor-deposited by sputtering on the glass substrate 108 to a thickness of about 300 nm, followed by patterning to a desired shape to form the gate electrodes 111 and the Cs electrodes 118. Then, a material such as SiNₓ or SiOₓ is deposited on substantially the whole surface of the glass substrate 108 by chemical vapor deposition (CVD) so as to cover the gate electrodes 111 and the Cs electrodes 118, thus forming the gate insulating film 113 with a thickness of about 350 nm. SiNₓ and SiOₓ are not the sole materials of the gate insulating film 113 but an anodized film obtained by anodizing the gate electrodes 111 and the Cs electrodes 118 may be used. Amorphous silicon (hereinafter abbreviated as “a-Si”) is deposited by CVD to a thickness of about 100 nm so that the channel layer 115 is provided above the gate electrodes 111 via the gate insulating film 113, which is followed by patterning to a desired shape to form the channel layer 115. Then, a-Si is deposited by CVD to a thickness of about 40 nm so that the contact electrodes 116 are provided on the channel layer 115, which is followed by patterning to a desired shape to form the contact electrodes 116.

A film of a metal such as tantalum or aluminum is vapor-deposited by sputtering on the contact electrodes 116 to a thickness of about 300 nm, which is followed by patterning to a desired shape to form the source electrodes 110 and the drain electrodes 112. SiNₓ is deposited by CVD to a thickness of about 300 nm so as to cover substantially the whole surface of the glass substrate 108 having the switching elements 107b and the charge storage capacitors 107c formed thereon, thus forming the insulating protective film 117. Thereafter, The SiNₓ film formed at the predetermined portions on the drain electrodes 112 where the contact holes 121 will be formed later is removed. A photosensitive acrylic resin or other material is deposited to a thickness of about 3 μm so as to cover substantially the whole surface of the insulating protective film 117, thus forming the interlayer insulating film 120. Photolithographic patterning is carried out in consideration of the positioning of the contact holes 121 in the insulating protective film 117, thus forming the contact holes 121.

An electroconductive, transparent amorphous oxide such as indium tin oxide (ITO) is vapor-deposited by sputtering on the interlayer insulating film 120 to form a film with a thickness of about 200 nm, which is followed by patterning to a desired shape to form the charge collecting electrodes 107a. In this process, electric continuity (short circuit) is established between the charge collecting electrodes 107a and the drain electrodes 112 via the contact holes 121 provided in the insulating protective film 117 and the interlayer insulating film 120. As described above in this embodiment, a so-called roof structure (mushroom electrode structure) is adopted in which the charge collecting electrodes 107a are overlaid on the switching elements 107b in the active matrix substrate 150, but non-roof structure may be adopted. The a-Si TFT is used for the switching elements 107b, but polysilicon (p-Si) may be used instead.

The electron injection blocking layer 106 with a thickness of preferably about 10 to 100 nm and more preferably about 20 to 100 nm is formed so as to cover the whole of the pixel array area of the active matrix substrate 150 formed as described above. After the formation of the crystallization inhibiting layer 105 having a thickness of about 10 to 100 nm, an amorphous selenium (a-Se) material doped with As or GeSb is deposited by vacuum evaporation to form the photoconductive layer 104 which has a thickness of about 0.5 mm to 1.5 mm and exhibits electromagnetic conductivity. Subsequently, the crystallization inhibiting layer 103 with a thickness of about 10 to 100 nm is formed, followed by formation of the hole injection blocking layer 102 with a thickness of about 30 to 100 nm. Finally, a material such as gold or aluminum is deposited by vacuum evaporation onto substantially the whole surface of the photoconductive layer 104 to form the bias electrode 101 having a thickness of about 200 nm.

It is possible to use Se—As compounds including a-As₂Se₃, Se—Ge compounds including GeSe and GeSe₂, and Se—Sb compounds including Sb₂Se₃ for the crystallization inhibiting layers 103 and 105. It is possible to use an oxide compound and a sulfide compound such as ZnS for the hole injection blocking layer 102, but ZnS capable of formation at a low temperature is preferable. However, since As₂Se₃ functions as the hole injection blocking layer, the hole injection blocking layer may not be formed in this case. A material such as Sb₂S₃ may be used for the electron injection blocking layer 106.

An amorphous material which is high in dark resistance, exhibits high electromagnetic conductivity upon irradiation with X-rays, and is capable of forming a large-area film at a low temperature by vacuum evaporation is preferably used for the photoconductive layer 104. An amorphous selenium (a-Se) film is used, but an amorphous selenium material doped with arsenic, antimony or germanium is a preferable material with thermal stability.

Of the layers constituting the solid-state radiation detector 100 as described above, the crystallization inhibiting layer 103, the photoconductive layer 104 and the crystallization inhibiting layer 105 may be formed using the vacuum evaporation apparatus of the present invention.

More specifically, film-forming material-evaporating devices which contain a plurality of film-forming materials to form their corresponding layers, respectively, are prepared for the respective layers to be formed, in the treatment chambers of the vacuum evaporation apparatus. On the electron injection blocking layer 106 formed beforehand on the active matrix substrate 150, the crystallization inhibiting layer 105, the photoconductive layer 104 and the crystallization inhibiting layer 103 are sequentially formed with the film-forming material-evaporating devices that were prepared for the respective layers.

This process enables manufacture of the solid-state radiation detector 100 having the crystallization inhibiting layer 103, the photoconductive layer 104 and the crystallization inhibiting layer 105, each of which is made of a compound of appropriate film-forming materials having a uniform composition ratio.

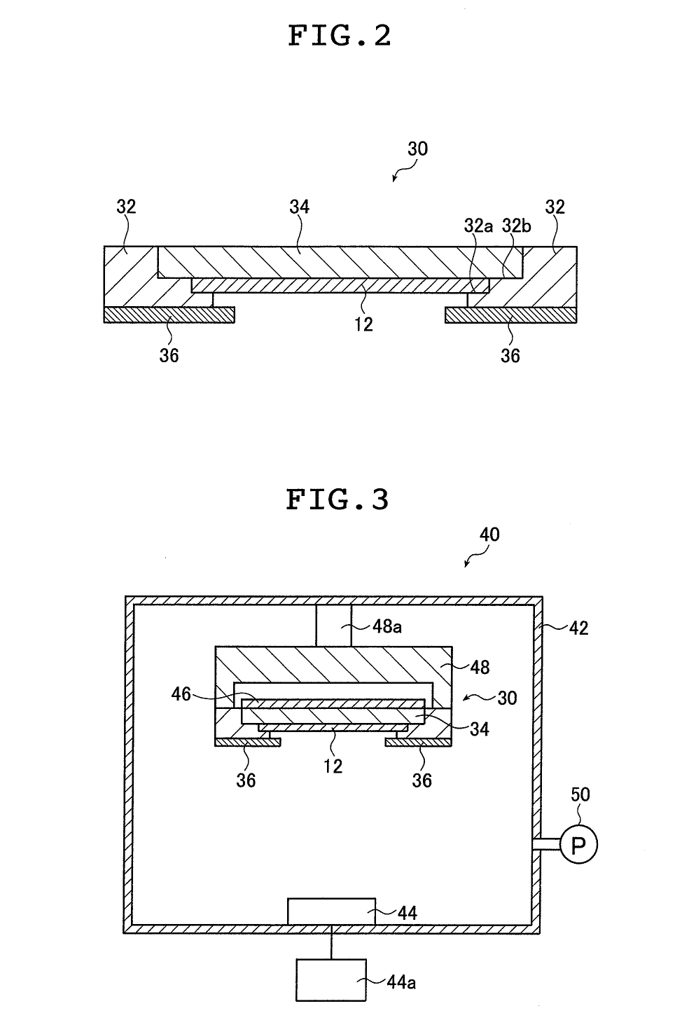

FIG. 2 is a sectional view showing the detailed structure of an example of a holder 30 for holding a support 12, which may be used in manufacturing the aforementioned solid-state radiation detector (FPD) 100 through vacuum evaporation in the vacuum evaporation apparatus of the embodiment to be described later. The support as used herein refers to one having the electron injection blocking layer 106 and the crystallization inhibiting layer 105 formed so as to entirely cover the pixel array area of the active matrix substrate 150.

The holder 30 shown in FIG. 2 is a substrate holder that may be used in the present invention and includes a frame 32 and a base 34 constituting a substrate holding portion which holds the support 12 in rectangular form serving as the above-mentioned substrate, and a mask 46 serving as a vapor deposition area-regulating member which regulates the area of the support 12 held on the frame 32 and the base 34 onto which the film-forming material is to be vapor-deposited.

The frame 32 is in a quadrangular shape, and as shown, includes a step portion 32a for holding the support 12 and a step portion 32b for fitting the base 34 therein.

The base 34 is fitted in the frame 32 from its back side and has the function of holding the support 12 in the frame 32.

The mask 36 is a quadrangular frame which is detachably engaged with the frame 32 on its front side and has a slightly smaller opening than the opening of the frame 32.

There is no particular limitation on how to engage the mask 36 with the frame 32 as long as the mask 36 can be detachably engaged with the frame 32, and various methods may be used as exemplified by a method using an engagement member such as a screw, a method which involves engaging a groove formed in one of the mask 36 and the frame 32 with a projection formed in the other, and a method which involves engaging a grooved projection having a spring action in one of the mask 36 and the frame 32 with a receiving portion in the other which can receive the grooved projection and has a stopper function.

In the present invention, the frame 32 and the base 34 constituting the substrate holding portion are made of a first material having a heat conductivity of at least 100 W/m·K and a specific gravity of up to 4.0×10³ kg/m³. The mask 36 serving as the vapor deposition area-regulating member is made of a second material which is different from the first material of the frame 32 and the base 34 and has a melting point of at least 13000C.

In the present invention, it is preferable for the first material of the frame 32 and the base 34 to be one member selected from among aluminum and aluminum alloys, and for the second material of the mask 36 to be one member selected from the group consisting of stainless steels, iron, titanium, platinum, chromium, molybdenum, tantalum, and tungsten.

Exemplary aluminum materials that may be preferably used include A1050 and A1100 materials, and exemplary aluminum alloys that may be preferably used include A2011, A2017, A2024, A5052, A5056, A5063, A6061, A6063 and A7075 materials.

Exemplary stainless steels that may be preferably used include SUS202, SUS303, SUS304, SUS305, SUS308, SUS309, SUS316, SUS330, SUS347, SUS403, SUS405, SUS410, SUS420, SUS430, SUS434, SUS651 and SUS661 (see, for example, URL:http://www.matweb.com/index.asp).

Tables 1 and 2 show each a list of heat conductivity, melting point and specific gravity of various metals (and alloys). Table 1 shows these metals in order of increasing heat conductivity, whereas Table 2 shows them in order of increasing melting point. Table 1 shows that aluminum and aluminum alloys are preferable materials of the substrate holding portion, whereas Table 2 shows that stainless steels, iron, titanium, platinum, chromium, molybdenum, tantalum and tungsten are preferable materials of the vapor deposition area-regulating member (mask). For the sake of comparison, Tables 1 and 2 show the same substances (except tungsten) in order of increasing heat conductivity and melting point, respectively.

TABLE 1

| | Heat | | Specific |
|---|---|---|---|
| | conductivity | Melting point | gravity |
| | [W/m · K] | [° C.] | [10³ kg/m³] |
| Stainless steel | 15 | 1300-1500 | 8 |
| Titanium | 18 | 1700 | 4.51 |
| Tantalum | 57 | 3072 | 16.8 |
| Chromium | 67 | 1890 | 7.19 |
| Platinum | 70 | 1768 | 20.34 |
| Iron | 84 | 1539 | 7.21 |
| Molybdenum | 147 | 2625 | 10.2 |
| Aluminum, | 117-260 | 476-660 | 2.7 |
| Aluminum alloy | | | |
| Copper | 403 | 1083 | 8.82 |
| Silver | 428 | 960 | 10.51 |

TABLE 2

| | | Heat | Specific |
|---|---|---|---|
| | Melting point | conductivity | gravity |
| | [° C.] | [W/m · K] | [10³ kg/m³] |
| Aluminum, | 476-660 | 117-260 | 2.7 |
| Aluminum alloy | | | |
| Silver | 960 | 428 | 10.51 |
| Copper | 1083 | 403 | 8.82 |
| Stainless steel | 1300-1500 | 15 | 8 |
| Iron | 1539 | 84 | 7.21 |
| Titanium | 1700 | 18 | 4.51 |
| Platinum | 1768 | 70 | 20.34 |
| Chromium | 1890 | 67 | 7.19 |
| Molybdenum | 2625 | 147 | 10.2 |
| Tantalum | 3072 | 57 | 16.6 |
| Tungsten | 3410 | 177 | 19.3 |

The holder 30 of this embodiment that may be used in an embodiment of a vacuum evaporation apparatus shown in FIG. 3 has the frame 32 and the base 34 which may be made of, for example, aluminum alloy A5083 having high thermal conductivity (heat conductivity: 117 W/m·K; specific gravity: 2.66×10³ kg/m³) and the mask 36 which may be made of SUS430 (melting point: 1425 to 1510° C.) so as to serve as a heat resistant member that may resist the use under vacuum heating.

FIG. 3 is a sectional view schematically showing the structure of a vacuum evaporation apparatus 40 of the embodiment under consideration, where selenium-containing layers are vapor-deposited on the support 12 to prepare the solid-state radiation detector (FPD) having the structure shown in FIG. 1A with the holder 30 of the structure as described above.

The vacuum evaporation apparatus of the embodiment under consideration (hereinafter also referred to simply as the “apparatus”) 40 basically includes a vacuum chamber 42, the holder 30 for holding the support 12 disposed within the vacuum chamber 42, a support mechanism 48 for supporting the holder 30 within the vacuum chamber 42, a heater 46 attached to the back surface of the holder 30, and a heating/evaporation means 44 for heating to evaporate the vapor deposition material (film-forming material), and is used to manufacture the solid-state radiation detector (FPD) which has a film formed by vapor-depositing selenium-containing layers on the surface of the support 12 held on the lower surface side of the holder 30.

As shown in FIG. 3, a vacuum pump 50 is connected to the vacuum chamber 42, the heating/evaporation means 44 is an evaporation source for heating to evaporate the selenium-containing vapor deposition material (film-forming material), and a heating power supply 44a is connected to the heating/evaporation means 44 and supplies power thereto.

In order to sequentially depositing different vapor deposition materials (film-forming materials), the number of the heating/evaporation means 44 used is usually more than one, but the means 44 is represented by one unit in FIG. 3. In this case, each of the heating/evaporation means 44 is preferably provided with a shutter for opening at the beginning of or closing at the end of deposition of the vapor deposition material (film-forming material) so that the vapor deposition components are selectively controlled.

The heater 46 is attached to the back surface of the base 34 in the holder 30 as referred to above and is used to uniformly heat the support 12 from its back surface through the base 34.

The vacuum chamber 42 is a known vacuum chamber (e.g. bell jar or vacuum vessel) that is formed of iron, stainless steel, aluminum, etc. and which is employed in apparatuses for vacuum evaporation.

The vacuum pump 50 constituting the vacuum pumping means is connected to the lateral surface of the vacuum chamber 42. For example, an oil diffusion pump is used for the vacuum pump. The vacuum pump is not particularly limited, but various types of vacuum pumps as used in vacuum evaporation apparatuses can be used as long as they help to attain the requisite vacuum level. For example, a cryogenic pump, a turbomolecular pump or any other pump may be used for the vacuum pump optionally in combination with a cryogenic coil. The vacuum chamber 42 of the apparatus 40 in the embodiment under consideration preferably attains a degree of vacuum of not more than 8.0×10⁻⁴ Pa.

The support mechanism 48 for supporting the holder 30 which holds the support 12 is used to hold the holder 30 by any known engaging method and is made of a material similar to that of the holder 30, that is, a material whose heat resistance is at substantially the same level as that of the holder 30.

The support mechanism 48 may be secured to a shaft 48a which is fixed. Alternatively, the support mechanism 48 may be rotated about the shaft 48a which is a rotary shaft.

The heating/evaporation means 44 for heating to evaporate the vapor deposition material (film-forming material) is disposed at the bottom of the vacuum chamber 42. As described above, the number of the heating/evaporation means 44 is usually more than one in order to form selenium-containing layers by vapor deposition. Above the heating/evaporation means 44 are provided shutters (not shown) for blocking out vapors of the vapor deposition materials emitted from the heating/evaporation means 44 so as to be controllable independently of each other. The shutter is controlled for its opening and closing to enable the step of evaporating each vapor deposition material (film-forming material) to be carried out.

Various types of heaters (sheathed heaters) may be used for the heating means of the heating/evaporation means 44. So-called resistance heating is also possible in which the vessels of the heating/evaporation means 44 are heated by electricity and used as heating sources. Electron beam heating, radio-frequency heating or other heating system may also be employed.

Various known shapes may be applied to the vessels (evaporation vessels) constituting the heating/evaporation means 44 depending on the amount of evaporation. For example, Vessels in various shapes such as boat-type, drum-type and pot-type may be used. The size (opening area, depth etc.) may also be determined as appropriate for the amount of evaporation.

When vapor deposition is performed in the layout described above, evaporation vessels containing the vapor deposition material are set in the vacuum chamber 42, and heated by a heater with the vacuum chamber 42 evacuated, thereby heating to melt and evaporate the vapor deposition material in the evaporation vessels. The thus evaporated vapor deposition material reaches the surface of the support 12 to form a film thereon. The shutter (not shown) is closed at the initial stage of heating the vapor deposition material, and is opened to start vapor deposition when heating proceeds and the evaporation rate reaches a steady state.

Upon formation (deposition) of a film with a predetermined thickness, the shutter is closed and clean air is introduced into the vacuum chamber 42. Then, the solid-state radiation detector (FPD) 100 after completion of vapor deposition is taken out of the vacuum chamber.

The solid-state radiation detector (FPD) 100 taken out of the vacuum chamber is cooled to a predetermined temperature before being subjected to various performance tests.

As a result of the completion of the vapor depositing operation in the vacuum chamber 42, the holder 30 holding the support 12 is checked for the state of the material vapor-deposited on its surface. As described above, this check is made to see whether the vapor deposition material (film-forming material) used in manufacturing the solid-state radiation detector (FPD) 100 is excessively deposited to the surface of the holder 30 and particularly the surface of the mask 36.

This check may be made every time one vapor depositing operation has been completed. However, if the amount of material deposited by one vapor depositing operation is known, this check may be made every time a predetermined number of vapor depositing operations have been completed. Alternatively, the check may not be made. For example, if the amount of vapor deposition material (film-forming material) deposited by one vapor depositing operation is determined beforehand, the period when the treatment for removing the deposited film-forming material is carried out by the aforementioned vacuum heating system may be determined by estimating therefrom.

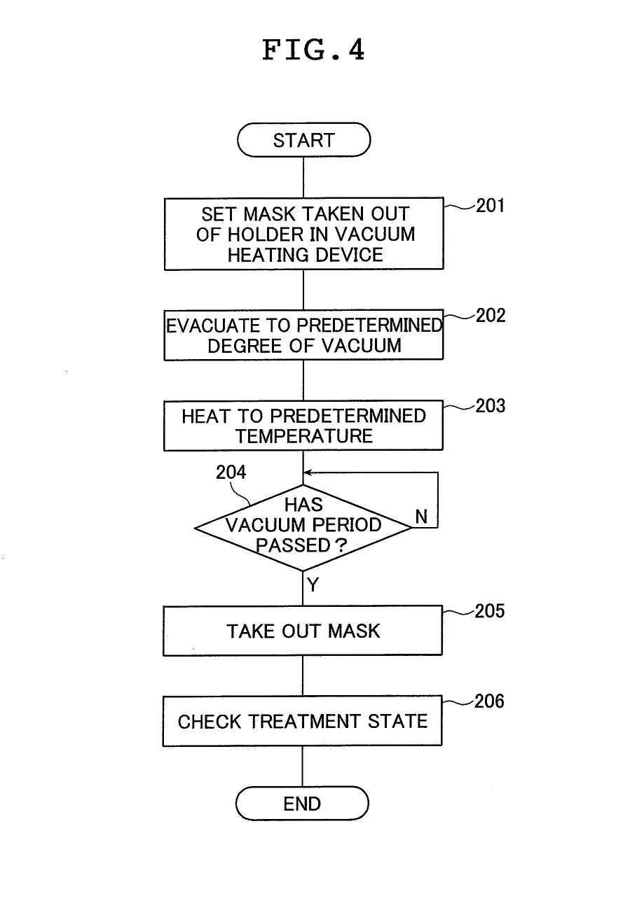

FIG. 4 is a flowchart illustrating the outline of the treatment carried out as a separate step of cleaning (treatment for removing the deposited film-forming material) by a vacuum heating system.

As shown in FIG. 4, in the treatment of a vacuum heating system for removing the deposited film-forming material, the mask 36 is first detached from the holder 30 in the vacuum chamber 42 of the vacuum evaporation apparatus by a specified method and is set in the vacuum heating device (Step 201).

After having been evacuated to a predetermined degree of vacuum (Step 202), the vacuum heating device is heated to a predetermined temperature (e.g., 250° C. to 400° C.) (Step 203) to evaporate and remove the material (film-forming material) having been vapor-deposited to the mask 36. This vacuum heating state is maintained for a preset period of time to clean the mask 36 (in the case of N in Step 204).

The melting point of the material used is the lower limit of the predetermined temperature. Its upper limit is determined by the heat resistance of the object to be heated. The actual temperature is determined as appropriate for the upper and lower limits and the desired cleaning time.

After the passage of the predetermined period of time (in the case of Y in Step 204), clean air is introduced into the vacuum heating device to restore the atmospheric pressure in the vacuum heating device while the vacuum heating device is cooled to room temperature. Then, the cleaned mask 36 is taken out of the vacuum heating device (Step 205).

Thereafter, the mask 36 taken out of the device is checked visually or otherwise to see the result of the treatment for removing the deposited film-forming material (Step 206). In addition to the degree to which the deposited film-forming material is removed, this check is preferably made to see whether there is deformation due to heat.

As described above, the holder 30 of this embodiment includes the frame 32 made of aluminum alloy A5083 having high thermal conductivity and the mask 36 made of SUS430 having high heat resistance. Therefore, the material (film-forming material) having been vapor-deposited to the mask 36 is completely removed by evaporation and an adverse effect such as thermal deformation of the mask 36 does not occur as long as the conditions for the treatment of the vacuum heating system for removing the deposited film-forming material are within the predetermined ranges.

In addition to the embodiment of the holder 30 configured as described above, various combinations of the above-mentioned materials that may be preferably used were subjected to the same treatment using the vacuum heating device, and every combination was found to achieve good results.

The same treatment was carried out for several combinations of the materials outside the range within which they may be preferably used, and every combination could not achieve good results.

These results could confirm the effectiveness of the vacuum evaporation apparatus of the present invention.

While the vacuum evaporation apparatus according to the present invention has been described above by way of illustration, the present invention is by no means limited to the foregoing embodiments and it should be understood that various improvement and modifications can of course be made without departing from the scope and spirit of the invention.

The present invention has been described with reference to the case of manufacturing a solid-state radiation detector of the type in which charges generated by irradiation with a radiation are stored and the stored charges are read with a thin film transistor (TFT). However, as described above, the present invention is not limited to this but may be advantageously applied to the case of manufacturing, for example, a solid-state radiation detector of a so-called optical reading type in which reading is made by making use of a semiconductor material that generates charges upon irradiation with light.

What is claimed is:

1. A vacuum evaporation apparatus which evaporates a film-forming material within an evaporation source to deposit by vacuum evaporation on a substrate held by a substrate holder to form a vapor-deposited film on said substrate, comprising:
a vacuum chamber;
said substrate holder which is disposed in said vacuum chamber and holds said substrate; and
said evaporation source which is disposed in said vacuum chamber and evaporates said film-forming material,
wherein said substrate holder comprises a substrate holding portion and a vapor deposition area-regulating member, said substrate holding portion being made of a first material having a heat conductivity of at least 100 W/m·K and a specific gravity of up to 4.0×10³ kg/m³ and said vapor deposition area-regulating member being made of a second material which is different from said first material and has a melting point of at least 1300° C.

2. The vacuum evaporation apparatus according to claim 1, wherein said vapor deposition area-regulating member is detachably mounted on said substrate holding portion.

3. The vacuum evaporation apparatus according to claim 1, wherein said first material is a member selected from the group consisting of aluminum and aluminum alloys, and said second material is a member selected from the group consisting of stainless steels, iron, titanium, platinum, chromium, molybdenum, tantalum, and tungsten.

4. The vacuum evaporation apparatus according to claim 2, wherein said substrate holding portion comprises a base disposed on a back side of said substrate, and a frame used to hold said substrate between said base and said frame, said frame comprising a first step portion which is formed inside said frame to hold said substrate, a second step portion which is formed further outside than said first step portion on the back side of said substrate held in said first step portion and is used to fit said base in said frame, and an opening which is formed on a side of a front surface of said substrate and through which the front surface of said substrate is open.
